(19) United States
(12) Patent Application Publication
(10) Pub. No.: US 2024/0234181 A1
(43) Pub. Date: Jul. 11, 2024

(54) Single-Pick-Multiple-Print Micro LED Mass Transfer with Elastomer Stamp

(71) Applicant: Apple Inc., Cupertino, CA (US)

(72) Inventors: Mingjing Ha, Cupertino, CA (US); Kuan H. Lu, Santa Clara, CA (US); Paul S. Drzaic, Morgan Hill, CA (US); Peter T. Carmichael, Campbell, CA (US); Siyi Liu, Dallas, TX (US); Yung-Yu Hsu, San Jose, CA (US); Stephen P. Bathurst, Lafayette, CA (US); Kevin T. Huang, Atherton, CA (US)

(21) Appl. No.: 18/562,211

(22) PCT Filed: May 17, 2022
(86) PCT No.: PCT/US2022/029681

§ 371 Date: Nov. 17, 2023

Related U.S. Application Data
(60) Provisional application No. 63/194,102, filed on May 27, 2021.

(51) Int. Cl. H01L 21/67; H01L 21/687; H01L 25/075

(52) U.S. Cl. CPC H01L 21/67144; H01L 21/6875; H01L 21/68778; H01L 21/68757; H01L 25/0753

(57) ABSTRACT

Conformable transfer devices and micro-transfer printing methods are described. In an embodiment, a conformable transfer devices includes first and second arrays of transfer heads with differential lengths to support a micro-transfer printing sequence including a single pick operation and multiple placement operations.

### BACKGROUND

### Field

Embodiments described herein relate to systems and methods for transferring micro devices.

### Background Information

Integration and packaging issues are one of the main obstacles for the commercialization of micro devices such as radio frequency (RF) microelectromechanical systems (MEMS) microswitches, light-emitting diodes (LEDs), and MEMS or quartz-based oscillators.

Traditional technologies for transferring of devices such as “direct printing” and “transfer printing” include transfer by wafer bonding from a transfer wafer to a receiving wafer. In both traditional and variations of the direct printing and transfer printing technologies, the transfer wafer is de-bonded from a device after bonding the device to the receiving wafer. In addition, the entire transfer wafer with the array of devices is involved in the transfer process.

In one process variation a transfer tool including elastomeric stamps is used to pick up an array of micro LEDs from a native wafer substrate and transfer the array of micro LEDs to a non-native receiving substrate, such as a display substrate. Such a sequence can be used to populate display substrates with monochrome or full-color micro LEDs. Elastomeric stamps may be used due to their large compliance to accommodate surface non-uniformity, compatibility with micro-sized devices and large area transfer, as well as simple fabrication sequences to form the elastomeric stamps. In such a transfer process Van der Waal forces can be used to attach the micro LEDs to the elastomeric stamps. The cycle time for the tool is determined by the average time from one pick to the next pick, inclusive of any downtime for inspection, maintenance, etc.

### SUMMARY

Systems and methods for high density transfer of arrays of micro devices from a donor substrate to a receiving substrate are described. In an embodiment, a conformable transfer device includes a base substrate, a first array of first transfer heads supported by the base substrate, and a second array of second transfer heads supported by the base substrate. In accordance with embodiments, the first and second transfer heads extend different lengths from the base substrate. For example, each first transfer head may include a first terminal contact surface extended a first orthogonal distance from the base substrate, and each second transfer head includes a second terminal contact surface extended a second orthogonal distance from the base substrate, where the first orthogonal distance is greater than the second orthogonal distance. Thus, in this example, the first transfer heads are longer than the second transfer heads.

In an embodiment, a micro-transfer printing method includes aligning a conformable transfer device over a donor substrate, contacting a first array of micro device on the donor substrate with the first array of first transfer heads of the conformable transfer device while contacting a second array of micro devices on the donor substrate with the second array of second transfer heads of the conformable transfer device, and picking up both the first array of micro devices from the substrate with the first array of first transfer heads and the second array of micro devices from the base substrate with the second array of second transfer heads. Where the first array of first transfer heads is longer than the second array of second transfer heads, the contacting operation may include compressing a height of the first array of first transfer heads more than the second array of second transfer heads.

The first and second arrays of micro devices may then be picked up from the donor substrate, followed by placing the first array of micro devices on the receiving substrate then subsequently placing the second array of micro devices on the receiving substrate. In an embodiment, an adhesive film spans over the receiving substrate, and the first array of micro devices is placed onto the receiving substrate without contacting the adhesive film with the second array of micro devices.

### BRIEF DESCRIPTION OF THE DRAWINGS

FIG. 1 is a schematic side-view illustration of a mass transfer tool assembly in accordance with an embodiment.

FIG. 2 is an isometric view illustration of a conformable transfer device mounted onto an articulating transfer head assembly in accordance with an embodiment.

FIG. 3A is a close-up schematic plan view illustration of an arrangement of an array of transfer heads with different lengths supported by a base substrate in accordance with an embodiment.

FIG. 3B is a close-up schematic plan view illustration of an arrangement of a clustered array of transfer heads with different lengths supported by a base substrate in accordance with an embodiment.

FIG. 4A is a schematic cross-sectional side view illustration taken along section X-X of FIGS. 3A-3B of a pair of first and second transfer heads in accordance with an embodiment.

FIG. 4B is a schematic cross-sectional side view illustration of relative dimensions of a transfer head in accordance with an embodiment.

FIG. 4C is a schematic cross-sectional side view illustration of a transfer head including a contact mesa with tapered sidewalls in accordance with an embodiment.

FIG. 4D is a schematic cross-sectional side view illustration of a transfer head extending from a bulk layer on a base substrate in accordance with an embodiment.

FIGS. 5A-5C are schematic cross-sectional side view illustrations for a single pick operation of pair of micro devices with a pair of transfer heads with different lengths in accordance with an embodiment.

FIGS. 6A-6B are schematic cross-sectional side view illustrations for a sequential placement sequence of a pair of micro devices with a pair of transfer heads with different lengths in accordance with an embodiment.

FIG. 7A is a close-up schematic cross-sectional side view illustration of a micro device that has been punched through an adhesive film during a placement operation in accordance with an embodiment.

FIG. 7B is a close-up schematic cross-sectional side view illustration of a micro device that has been placed onto an adhesive film during a placement operation in accordance with an embodiment.

FIG. 7C is a close-up schematic cross-sectional side view illustration of a micro device that has been placed onto an adhesive film including an embedded electrically conductive bonding mesa during a placement operation in accordance with an embodiment.

FIG. 8A is a close-up schematic cross-sectional side view illustration of a receiving substrate including a continuous adhesive film spanning over and between an array of bank structures in accordance with an embodiment.

FIG. 8B is a close-up schematic cross-sectional side view illustration of a receiving substrate including a patterned adhesive film over an array of bank structures where the adhesive film has been removed between adjacent bank structures in accordance with an embodiment.

FIGS. 9A-9D are close-up schematic plan view illustrations for arrangements of arrays of transfer heads aligned over arrays of landing pads of display substrates in accordance with embodiments.

### DETAILED DESCRIPTION

Embodiments describe systems and methods for high density transfer of arrays of micro devices from a donor substrate to one or more receiving substrates. For example, the arrays of micro devices may be micro LEDs. While some embodiments are described with specific regard to micro LEDs, the embodiments of the invention are not so limited and certain embodiments may also be applicable to other micro devices such as diodes, transistors, integrated circuit (IC) chips, MEMS, bio-samples, etc.

In one aspect, it has been observed that the cycle time for traditional printing sequences using elastomeric stamps is time consuming due to a slow releasing operation, and cleaning operation after each transfer. In accordance with embodiments, mass transfer tools and methods of operation are described in which conformal transfer devices, or elastomeric stamps, are used in a way which can reduce cycle time.

In one aspect, single-pick-multiple-print processes are described which can facilitate a reduction in cycle time by picking up a high density of micro devices from a donor substrate and sequentially placing groups of the micro devices onto one or more receiving substrates. This may be achieved by integration of an adhesive film on the receiving substrate to reduce placement time, along with conformal transfer devices, or elastomeric stamps, designed with different transfer head lengths, which can allow for sequential placement of groups of micro devices while avoiding contact of the non-transferred micro devices with the receiving substrate. In an embodiment, a mass transfer tool includes an articulating transfer head assembly that carries a conformable transfer device, or elastomeric stamp, that, depending upon size of the elastomeric stamp and specifications for the receiving substrate, may include thousands of individual transfer heads.

In an embodiment, a conformable transfer device includes a base substrate, a first array of first transfer heads supported by the base substrate, and a second array of second transfer heads supported by the base substrate. In accordance with embodiments, the first and second transfer heads extend different lengths from the base substrate. For example, each first transfer head may include a first terminal contact surface extended a first orthogonal distance from the base substrate, and each second transfer head includes a second terminal contact surface extended a second orthogonal distance from the base substrate, where the first orthogonal distance is greater than the second orthogonal distance. Thus, in this example, the first transfer heads are longer than the second transfer heads.

In an embodiment, a micro-transfer printing method includes aligning a conformable transfer device over a donor substrate, contacting a first array of micro devices on the donor substrate with the first array of first transfer heads of the conformable transfer device while contacting a second array of micro devices on the donor substrate with the second array of second transfer heads of the conformable transfer device, and picking up both the first array of micro devices from the substrate with the first array of first transfer heads and the second array of micro devices from the base substrate with the second array of second transfer heads. Where the first array of first transfer heads is longer than the second array of second transfer heads, the contacting operation may include compressing a length (or height) of the first array of first transfer heads more than the second array of second transfer heads.

The first and second arrays of micro devices may then be pick up from the donor substrate, followed by placing the first array of micro devices on the receiving substrate then subsequently placing the second array of micro devices on the receiving substrate. In an embodiment, an adhesive film spans over receiving substrate, and the first array of micro devices is placed onto the receiving substrate without contacting the adhesive film with the second array of micro devices. During this placement operation, the first array of micro devices can be placed onto the adhesive film, or punched through the adhesive film. In either configuration, the adhesive film can assist with releasing the first array of micro devices, and increased cycle time.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “to”, “between”, “spanning” and “on” as used herein may refer to a relative position of one layer with respect to other layers. One layer “over”, “spanning” or “on” another layer or bonded “to” or in “contact” with another layer may be directly in contact with the other layer or may have one or more intervening layers. One layer “between” layers may be directly in contact with the layers or may have one or more intervening layers.

The terms “micro” device or “micro” LED as used herein may refer to the descriptive size of certain devices or structures in accordance with embodiments. As used herein, the term “micro” is meant to refer to the scale of 1 to 300 μm. For example, each micro device may have a maximum length or width of 1 to 300 μm, 1 to 100 μm, or less. In some embodiments, the micro devices (e.g. micro LEDs) may have a maximum length and width of 20 μm, 10 μm, or 5 μm. However, it is to be appreciated that embodiments of the present invention are not necessarily so limited, and that certain aspects of the embodiments may be applicable to larger, and possibly smaller size scales.

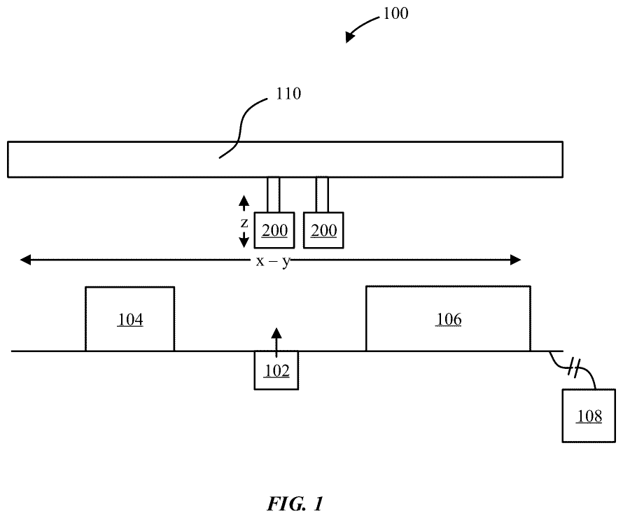

Referring now to FIG. 1 a schematic side-view illustration is provided of a mass transfer tool in accordance with an embodiment. Mass transfer tool 100 may include one or more articulating transfer head assemblies 200, each for picking up an array of micro devices from a carrier (donor) substrate held by a carrier substrate stage 104 and for transferring and releasing the array of micro devices onto a receiving substrate held by a receiving substrate stage 106. In an embodiment, an upward facing inspection camera 102 is located between the carrier substrate stage 104 and the receiving substrate stage 106. In this manner, the underside of an articulating transfer head assembly 200 (e.g. a conformable transfer device carrying a group of micro devices) may be inspected by the inspection camera while the articulating transfer head assembly 200 moves between the carrier substrate stage 104 and receiving substrate stage 106 to verify efficacy of the transfer operations. Operation of mass transfer tool 100 and articulating transfer head assembly 200 may be controlled at least in part by a computer 108.

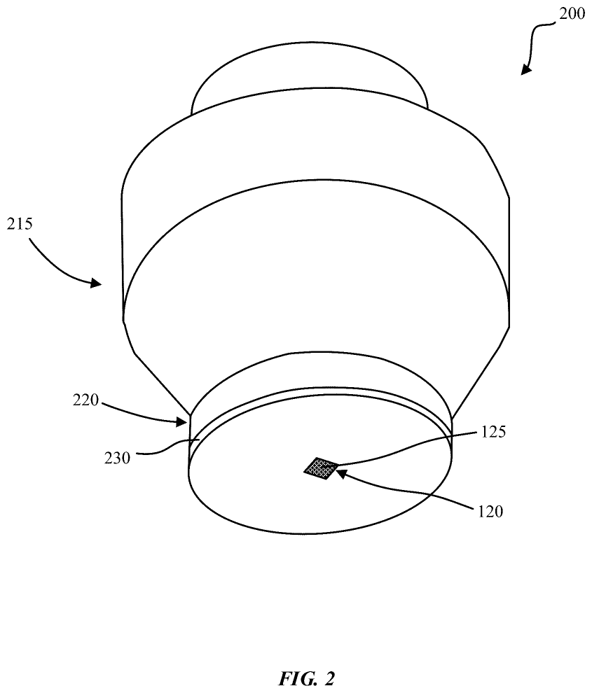

Referring to FIG. 2, a perspective view of an articulating transfer head assembly 200 is shown in accordance with an embodiment. An articulating transfer head assembly 200 may be used in the mass transfer tool 100 to transfer micro devices to or from a substrate, e.g., receiving substrate or donor substrate, using conformable transfer device 120, or elastomeric stamp. In an embodiment, the conformable transfer device 120 includes an array of transfer heads 125 to transfer a corresponding array of micro devices. In an embodiment each transfer head has a terminal contact surface characterized by a maximum dimension of 1-300 μm in both the x- and y-dimensions. In an embodiment, each transfer head contact surface has a maximum lateral dimension of 1 to 100 μm, or less. In some embodiments, each transfer head contact surface has a maximum length and width of 20 μm, 10 am, or 5 μm. Similarly, each micro device, such as an LED or chip, may have a maximum lateral dimension of 1-300 μm or 1-100 μm, such as 20 μm, 10 μm, or 5 μm. The articulating transfer head assembly 200 can include features that allow for the exchange of the conformable transfer device 120.

Referring to both FIGS. 1-2, computer 108 may control the operation of articulating transfer head assembly 200 of the mass transfer tool 100. For example, articulating transfer head assembly 200 may include an actuator assembly for adjusting the conformable transfer device 120 retained by the transfer head assembly with at least three degrees of freedom, e.g., tipping, tilting, and movement in a z direction, based on feedback signals received from various sensors of the mass transfer tool 100. Computer 108 may also control movement of the articulating transfer head assembly 200 along translation track 110 (e.g. x direction) over the carrier substrate stage 104 and receiving substrate stage 106. Additional actuators may be provided, e.g., between mass transfer tool 100 structural components and articulating transfer head assembly 200, carrier substrate stage 104, or receiving substrate stage 106, to provide movement in the x, y, or z direction for one or more of those sub-assemblies. For example, a gantry may support articulating transfer head assembly 200 and move articulating transfer head assembly 200 along an upper beam, e.g., in a direction parallel to an axis of motion of translation track 110. Thus, an array of transfer heads on conformable transfer device 120, supported by transfer head assembly 200, and a target substrate (e.g. supported by carrier substrate stage 104 or receiving substrate stage 106) may be precisely moved relative to each other within all three spatial dimensions.

The articulating transfer head assembly 200 in accordance with embodiments may provide for negligible lateral or vertical parasitic motion for small movements of conformable transfer device 120, e.g., motion less than about 5 mrad about a neutral position. In an embodiment, the articulating transfer head assembly includes a tip-tilt assembly 215 and a piezoelectric stage assembly 220 mounted underneath the tip-tilt assembly 215. Together the tip-tilt assembly 215 and the piezoelectric stage assembly 220 may provide six degrees of motion. Specifically, the tip-tilt assembly 215 may provide tip (θx) and tilt (θy), where the piezoelectric stage assembly 220 provides z motion, x motion, y motion, and rotation (θz). In the particular embodiment illustrated a mounting plate 230 is secured underneath the piezoelectric stage assembly 220. The conformable transfer device 120 can be mounted on the mounting plate 230 using suitable techniques such as electrostatic clamps, vacuum, or mechanical clips.

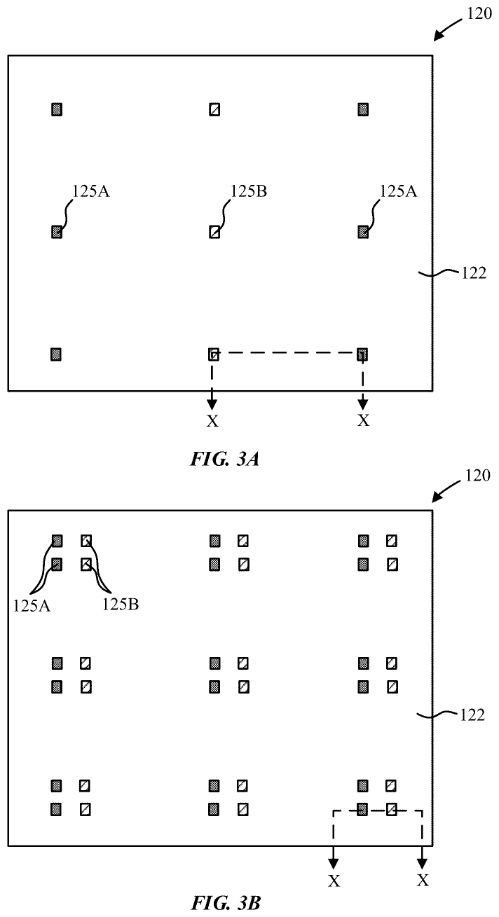

Referring now to FIGS. 3A-3B, close-up schematic plan view illustrations are provided for conformable transfer devices 120 including arrays of transfer heads of different lengths supported by a base substrate 122. In the embodiment illustrated in FIG. 3A, a first array of first transfer heads 125A and second array of second transfer heads 125B are arranged in columns, and uniformly spaced. It is to be appreciated that this is an exemplary implementation and embodiments are not so limited. The embodiment illustrated in FIG. 3B includes a more intricate arrangement of the arrays of first transfer heads 125A and second transfer heads 125B into clusters. For example, these clusters may be more densely arranged than pixel pitch on a receiving substrate. While both implementations can be used for single-pick-multiple-pace transfer sequences, the clustered arrangement may be suitable for a greater number of sequential placements, further reducing overall cycle time. For example, the illustrated clusters including four total transfer heads, two first transfer heads 125A and two second transfer heads 125B, may be used for four total sequential placements, following a single pick operation.

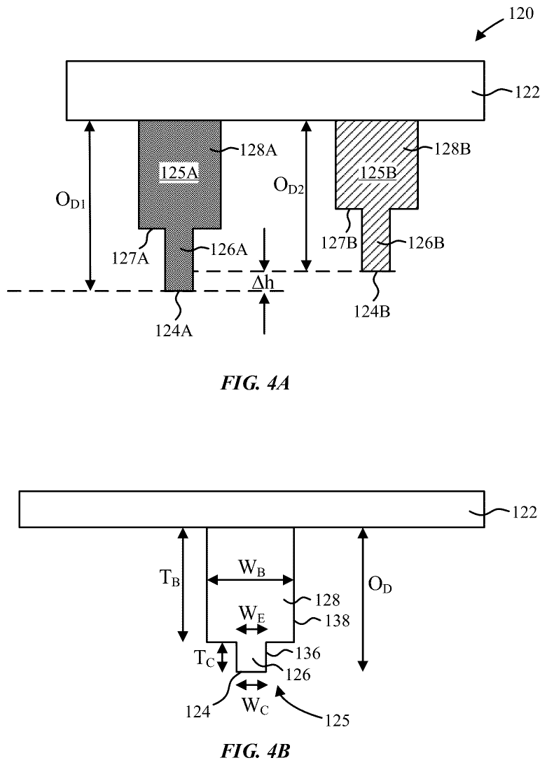

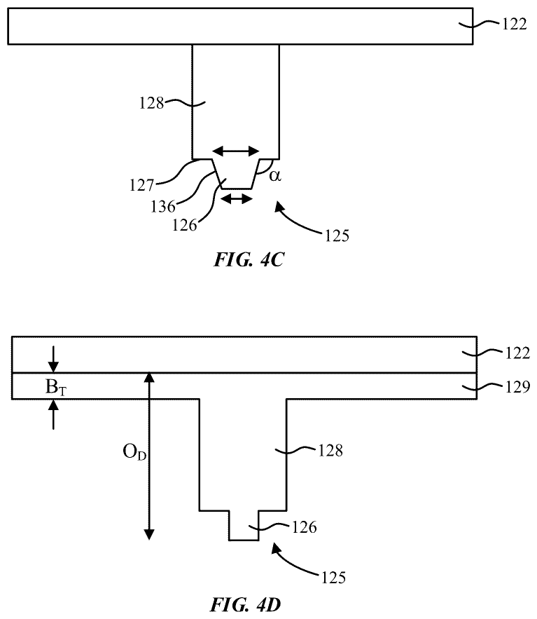

FIG. 4A is a schematic cross-sectional side view illustration taken along section X-X of FIGS. 3A-3B of a pair of first and second transfer heads in accordance with an embodiment. As shown, the conformal transfer device 120 includes a base substrate 122 and a first array of first transfer heads 125A supported by the base substrate and a second array of second transfer heads 125B supported by the base substrate. Each first transfer head 125A includes a first terminal contact surface 124A extended a first orthogonal distance O_{D1} from the base substrate 122, and each second transfer head 125B includes a second contacts surface 124B extended a second orthogonal distance O_{D2} from the base substrate 122. In this illustrative example, the first orthogonal distance O_{D1} from is greater than the second orthogonal distance O_{D2}, resulting in a differential length or height (Δh) of the first transfer heads 125A and the second transfer heads 125B.

In accordance with embodiments, the first transfer heads 125A each include a first contact mesa 126A which includes the first contact surface 124A, and the second transfers heads 125B each include a second contact mesa 126B which includes the second contact surface 124B. Additionally, the first transfer heads 125A may include a first base mesa 128A with the first contact mesa 126A extending from a first extension surface 127A of the first base mesa 128A, and the second transfer heads 125B may include a second base mesa 128B with the second contact mesa 126B extending form a second extension surface 127B of the second base mesa 128B.

The base substrate 122 may be a rigid material in some embodiments, and may be formed of a suitable material such as glass, silicon, etc. The first transfer heads 125A and the second transfer heads 125B, or portions thereof, may be formed of the same or different materials. For example, the first and second contact mesas 126A, 126B may be formed of the same material, such as polymer. In a specific implementation the polymer may be polydimethylsiloxane (PDMS). Likewise, the first and second base mesas 128A, 128B may be similarly formed, and may be integrally formed with the first and second contact mesas 126A, 126B. In an exemplary fabrication sequence, the arrays of transfer heads can be formed by casting onto the base substrate 122, curing, and mold removal.

The transfer heads with different lengths in accordance with embodiments may be designed in a manner to endure a certain amount of deformation when picking up micro devices from a donor substrate and placement of the micro devices onto a receiving substrate. For example, the deformation may be related to a certain amount of z-direction overdrive of the articulating transfer head assembly and connected conformable transfer device in order to ensure contact is made with the target structure with sufficient force/pressure.

During a simultaneous pick operation the contact mesas of the shorter transfer heads may need to output enough force/pressure to ensure contact is made with the micro device being picked up, while the contact mesas of the longer transfer heads remain in the elastic region and do not output too much force/pressure to damage the micro devices being picked up.

During a sequential placement operation, and in particular when placing micro devices with the longer transfer heads (e.g. first transfer heads 125A) first, the contact mesas of the longer transfer heads may need to output enough force/pressure for bonding with the receiving substrate and release (placement). This force is related to the amount of print overdrive. The contact mesas of the shorter transfer heads (e.g. second transfer heads 125B), or more specifically the micro devices held by the shorter transfer heads, in this embodiment should have enough clearance to not touch the underlying surface of the receiving substrate. If the micro devices need to be pushed through an adhesive film, the adhesive film thickness should be considered.

In an embodiment, after placement of the micro devices held by the longer transfer heads, the micro devices held by the shorter transfer heads may then be placed. In this case the contact mesas of the shorter transfer heads may need to output enough force/pressure for bonding with the receiving substrate and release (placement). This force is also related to amount of print overdrive. At this point, the contact mesas of the longer transfer heads (e.g. first transfer heads 125A) should have enough clearance not to touch the underlying surface of the receiving substrate. If the micro devices need to be pushed through an adhesive film, the adhesive film thickness should be considered.

Thus, in order implement a reliable process, a certain clearance is to be maintained from the receiving substrate with the non-bonding transfer heads and, if present, the micro devices thereon. This may be aided by control of z-direction overdrive while meeting target force/pressure. Furthermore, topography of the receiving substrate and thickness of any adhesive film can be controlled.

Referring now to FIGS. 4B-4D several variations are illustrated for controlling the transfer head 125 design, which can contribute to z-direction overdrive. As shown, the base mesa 128 can be characterized by a width W_{B} and thickness T_{B}, and the contact mesa 126 is characterized by a thickness T_{C}, contact surface 124 width W_{C}, and extension surface width W_{E}. Together the base mesa 128 thickness T_{B} and the contact mesa 126 thickness T_{C} contribute to the orthogonal distance O_{D} from the base substrate 122. While illustrated as straight, the sidewalls 136 of the contact mesa 126 and/or the sidewalls 138 of the base mesa 128 can be tapered. For example, as illustrated in FIG. 4C the sidewalls 136 of the contact mesa 126 can be tapered to form a non-perpendicular angle with the extension surface 127 of the base mesa 128. Tapered contact mesas 126 may lead to increased reactive pressure.

Referring briefly back to FIG. 4A, the transfer heads may optionally include only the contact mesa, or also the contact mesa and base mesa. It is to be appreciated that embodiments are not limited to these particular configurations, and instead they are to be understood as exemplary implementations. The contact mesas for the first and second transfer heads 125A, 125B may have the same or different dimensions. The base mesas for the first and second transfer heads 125A, 125B may have the same or different dimensions. For example, the first base mesa 128A and the second base mesa 128B may have the same thicknesses, with length differential controlled by differently sized first contact mesas 126A and second contact mesas 126B. Alternatively, the first base mesa 128A and the second base mesa 128B have different thicknesses T_{B} in the orthogonal direction from the base substrate 122. Generally, shorter and wider mesa structures can lead to higher reactive pressure. Additionally, stiffer material selection for the transfer heads can lead to higher reactive pressure.

Referring now to FIG. 4D, the base mesa 128 is illustrated as extending from a bulk layer 129 on the base substate 122. For example, the bulk layer 129 and the base mesa 128 may be integrally formed, and formed of the same material. Addition of the bulk layer 129, and increased thickness B_{T} of the bulk layer, may lead to lower reactive pressure. In some embodiments, the base mesa 128 extends directly from the base substrate 122, which may lead to higher reactive pressure. Where a base mesa 128 is not present, the contact mesa 126 can extend directly from the base substrate 122 or bulk layer 129.

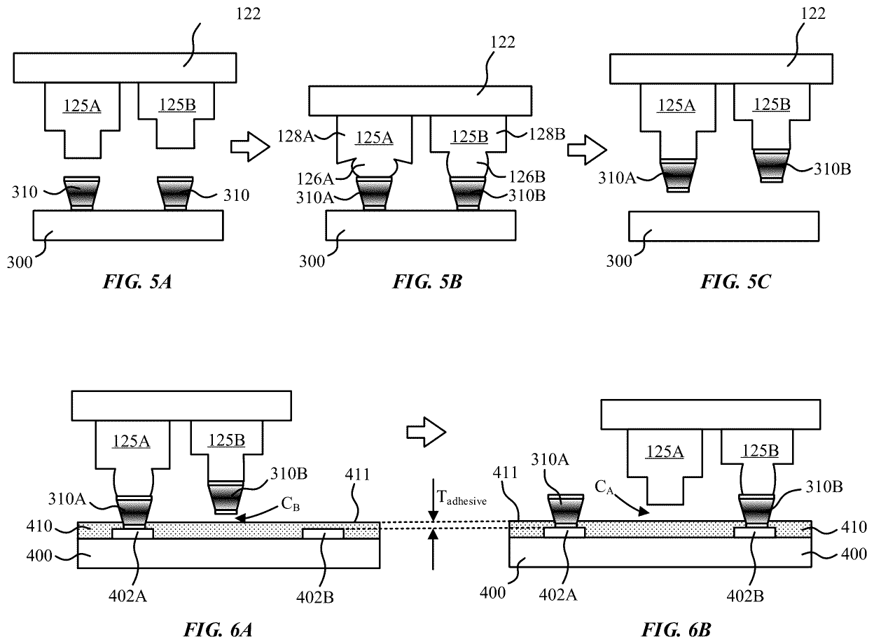

FIGS. 5A-5C are schematic cross-sectional side view illustrations for a single pick operation of pair of micro devices with a pair of transfer heads with different lengths in accordance with an embodiment. As shown in FIG. 5A micro-transfer printing method may begin with aligning a conformable transfer device over a donor substrate 300. Specifically, the transfer heads of the conformable transfer device area aligned over micro devices 310, such as micro LEDs, supported on the donor substrate 300. In the particular embodiment illustrated the first transfer head 125A and second transfer head 125B described with regard to FIG. 4A are aligned over micro devices 310. The first array of micro devices 310A on the donor substrate is then contacted with the first array of first transfer heads 125A while contacting the second array of micro devices 310B on the donor substrate with the second array of second transfer heads 125B as shown in FIG. 5B. In such a sequence, the first array of first transfer heads 125A contact the first array of micro devices 310A first, while the articulating transfer head assembly and conformable transfer device continue to be driven toward the donor substrate 300 until the second array of transfer heads 125B contacts the second array of micro devices 310B with sufficient force/pressure to ensure contact. In an embodiment, deformation of the longer first transfer heads 125A (Deformation A) may correspond to the sum of the pickup overdrive distance (Overdrive__{pickup}) and differential length or height (Δh) of the first and second transfer heads 125A, 125B, while deformation of the second transfer heads 125B corresponds to the pickup overdrive distance as shown in Equations 1-2 below:

$$Deformation A = ( {Overdrive\_}_{pickup} ) + Δ h \qquad ( 1 )$$

$$Deformation B = {Overdrive\_}_{pickup} \qquad ( 2 )$$

As shown, the longer first transfer heads 125A experience a greater amount of deformation than the shorter second transfer heads 125B. Both the first and second arrays of micro devices 310A, 310B can then be picked up from the donor substrate 300 with the first array of first transfer heads 125A and the second array of second transfer heads 125B as shown in FIG. 5C.

Following pick up of the arrays of micro devices from the donor substrate, the articulating transfer head assembly and conformable transfer device 120 can be translated to one or more receiving substrates for sequential placement of the micro devices. FIGS. 6A-6B are schematic cross-sectional side view illustrations for a sequential placement sequence of a pair of micro devices with a pair of transfer heads with different lengths in accordance with an embodiment. In the particular embodiment illustrated, an adhesive film 410 is formed over the receiving substrate and spans over landing pads 402 of the receiving substrate 400. In an embodiment, the adhesive film is either spin-coated or slot-die-coated on the receiving substrate first, followed by a soft bake prior to micro device transfer. In this manner, the adhesive film material is flowable after soft bake and can be punched through by the micro devices. The tackiness of adhesive film surrounding bond joint assists micro devices staying on landing pads. After micro device transfer, a follow-up hard bake is applied to fully cure the adhesive film. The adhesive film material may be formed of a variety of polymeric materials, including thermosets such as epoxy, etc.

Referring now to FIG. 6A, in the illustrated embodiment the first array of micro devices 310A is placed on the receiving substrate 400 prior to placing the second array of micro devices 310B on the receiving substrate 400. Specifically, the first array of micro devices 310A can be placed over a first array of landing pads 402, and the second array of micro devices 310B does not contact the adhesive film 410 while placing the first array of micro devices 310A. In the particular embodiment illustrated the first array of micro devices 310A is punched through the adhesive film 410 to make direct contact with the first array of landing pads 402. In this instance the amount of deformation of the first transfer heads 125A will be proportional to the overdrive distance during printing to provide the specified force/pressure for bonding to the first array of micro devices 310A to the first array of landing pads 402, as indicated by Equation 3:

$$Deformation A = {Overdrive\_}_{print \_ A} \qquad ( 3 )$$

As illustrated, a certain clearance distance C_{B} needs to be maintained between the second array of micro devices 310B held by the second transfer heads 125B and a top surface 411 of the adhesive film 410. Assuming thickness of the first and second arrays of micro devices 310A, 310B are the same, this clearance distance may be proportional to the differential length or height (Δh) of the first and second transfer heads 125A, 125B less the thickness of the adhesive film 410 covering the landing pads 402 T_{adhesive}, and less the overdrive distance (Overdrive__{print_A}) as provided in Equation 4 below:

$$Clearance {C}_{B} = Δ h - {T}_{adhesive} - {Overdrive\_}_{print \_ A} \qquad ( 4 )$$

Once the first array of micro devices 310A has been placed onto the first array of landing pads 402A, the articulating transfer head assembly and conformable transfer device 120 can be translated to position with the second array of second transfer heads 125B and second array of micro devices 310B located over the second array of landing pads 402B. Referring to FIG. 6B, in the illustrated embodiment the second array of micro devices 310B is then placed on the receiving substrate with the second array of second transfer heads 125B. In the particular embodiment illustrated the second array of micro devices 310B is punched through the adhesive film 410 to make direct contact with the second array of landing pads 402B. In this instance the amount of deformation of the second transfer heads 125B will be proportional to the overdrive distance during printing to provide the specified force/pressure for bonding to the second array of micro devices 310B to the second array of landing pads 402B, as indicated by Equation 5:

$$Deformation B = {Overdrive\_}_{print \_ B} \qquad ( 5 )$$

As shown, the first array of first transfer heads 125A will not contact the adhesive film 410. The resulting clearance distance C_{A} distance may be proportional to the sum of the thickness of the first array of micro devices 310A (T_{MD_A}) less the differential length or height (Δh) of the first and second transfer heads 125A, 125B, less the thickness of the adhesive film 410 covering the landing pads 402 T_{adhesive}, and less the overdrive distance (Overdrive__{print_B}) as provided in Equation 6 below:

$$Clearance {C}_{A} = {T}_{MD \_ A} - Δ h - {T}_{adhesive} - {Overdrive\_}_{print \_ B} \qquad ( 6 )$$

It is to be appreciated that the above equations 1-6 provided with regard to the micro-transfer printing operations in FIGS. 5A-5C and FIGS. 6A-6B have been provided for illustrative purposes only. It is understood the equations are approximations, and actual values may vary, in particular with variations in receiving substrate 400 topography, micro device 310 variation, transfer head variation, etc. Furthermore, the above equations presume a single pick, two placement sequence. However, the equations can vary with the inclusion of additional placements.

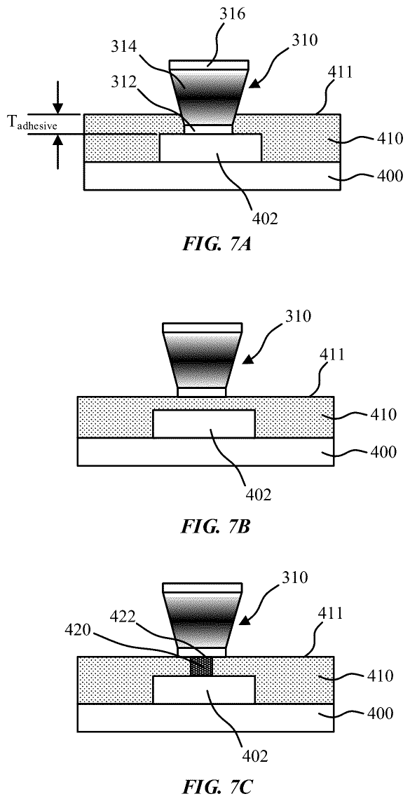

FIG. 7A is a close-up schematic cross-sectional side view illustration of a micro device 310 that has been punched through an adhesive film 410 during a placement operation in accordance with an embodiment. FIG. 7A is consistent with the sequence illustrated in FIGS. 6A-6B. In the particular embodiment illustrated, the micro device 310 may be a micro LED including a bottom conductive contact 312 bonded to the landing pad 402, a p-n diode 314, and optionally a top conductive contact 316, which may be transparent or semi-transparent. As shown, a portion of the micro device 310 can be punched through a thickness (T_{adhesive}) of the adhesive film 410 to contact the landing pad 402. Thus, a portion of the micro device 310 can be embedded within the adhesive film 410. In an embodiment, the p-n diode 314 is formed of an inorganic semiconductor-based material, such as II-VI or III-V material.

FIG. 7B is a close-up schematic cross-sectional side view illustration of a micro device 310 that has been placed onto a top surface 411 of an adhesive film 410 during a placement operation in accordance with an embodiment. In a micro-transfer printing sequence such as FIG. 7B placing either the first or second array of micro devices 310 on the receiving substrate 400 includes placing the corresponding array of micro devices onto the adhesive film 410 spanning over the corresponding array of landing pads 402. The adhesive film 410 may aid in the placement operation. In a multiple-place sequence, multiple arrays of micro devices can be placed onto the top surface 411 of the adhesive film 410. This may then be followed by a reflow (thermal) process, where surface tension from the adhesive film 410 can pull the micro devices 310 down to touch the landing pads 402 and for the requisite bonding. Such a processing sequence can facilitate a reduction in clearance height, effectively removing the adhesive thickness (T_{adhesive}) from the equation.

FIG. 7C is a close-up schematic cross-sectional side view illustration of a micro device that has been placed onto a top surface 411 of an adhesive film 410 including an embedded electrically conductive bonding mesa 420 during a placement operation in accordance with an embodiment. In a micro-transfer printing sequence such as FIG. 7C placing either the first or second array of micro devices 310 on the receiving substrate 400 includes placing the corresponding array of micro devices onto the adhesive film 410 spanning over the corresponding array of landing pads 402. The adhesive film 410 may aid in the placement operation. Furthermore, the embedded conductive bonding mesa 420 can assist with bond formation between the micro device 310 and underlying landing pad 402. This may be aided by a reflow (thermal) process after placement. In an embodiment, the electrically conductive bonding mesa 420 is a solder material such as indium, etc. that can be reflowed at lower solder reflow temperatures. Such a processing sequence can facilitate a reduction in clearance height, effectively removing the adhesive thickness (T_{adhesive}) from the equation. In an embodiment, a top surface 422 of the electrically conductive bonding mesa 420 and the top surface 411 of the adhesive film 410 are coplanar prior to placement. For example, this may be achieved by a planarization operation, such as chemical mechanical planarization (CMP).

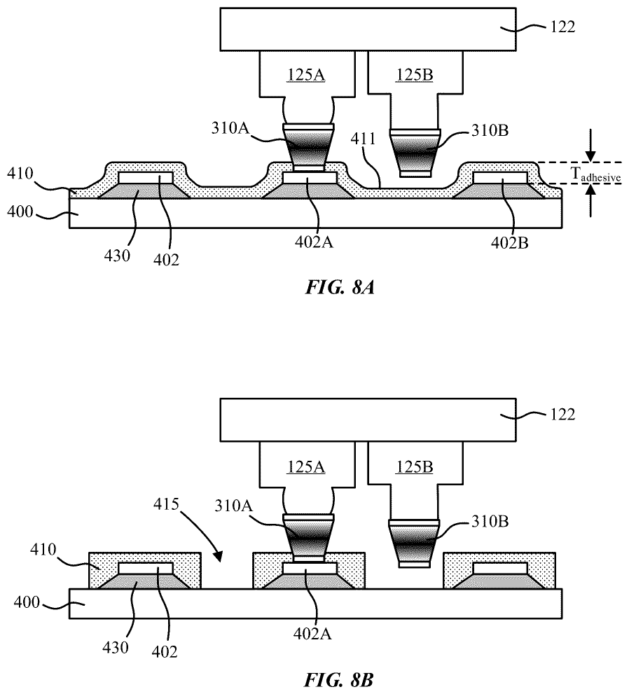

Referring now to FIG. 8A, a close-up schematic cross-sectional side view illustration is provided of a receiving substrate 400 including a continuous adhesive film 410 spanning over and between an array of bank structures 430 in accordance with an embodiment. As shown, the first array of landing pads 402A is located on a first array of bank structures 430, and the second array of landing pads 402B is located on a second array of bank structures 430. In an embodiment, placing the first array of micro devices 310 on the receiving substrate 400 includes placing the first array of micro devices over the first array of landing pads 402 while orienting the second array of micro devices 310 laterally adjacent the second array of bank structures 430. The placement operation may include punching through the adhesive film 410 as illustrated in FIG. 7A and FIGS. 8A-8B, or placing the micro devices 310 on top of the adhesive film 410 as illustrated in FIGS. 7B-7C.

FIG. 8B is a close-up schematic cross-sectional side view illustration of a receiving substrate 400 including a patterned adhesive film 410 over an array of bank structures 430 where the adhesive film 410 has been removed in trenches 415 through the adhesive film 410 between adjacent bank structures 430 and landing pads 402 in accordance with an embodiment. As shown, during the first placement operation of the first array of micro devices 310A on the receiving substrate 400 with the longer first array of transfer heads 125A, the second array of micro devices 310B is not oriented directly over the adhesive film 410, which has been removed.

Thus, clearance distances during the first and second placement operations in accordance with embodiments, can depend upon a variety of factors, including those in Equations 4 and 6, as well as variations in micro device 310 thickness, placement technique onto or through an adhesive film 410, receiving substrate 400 topography control with bank structures 430, patterning of the adhesive film, etc.

Referring briefly back to FIGS. 3A-3B two exemplary conformable transfer device 120 transfer head 125 layouts are provided to support the single-pick-multiple-print transfer sequences in accordance with embodiments, where multiple transfer heads 125 can be grouped into a larger number of clusters including intra-cluster pitch that is mis-matched with landing pad pitch (or pixel pitch) on a receiving substrate to support multiple printing.

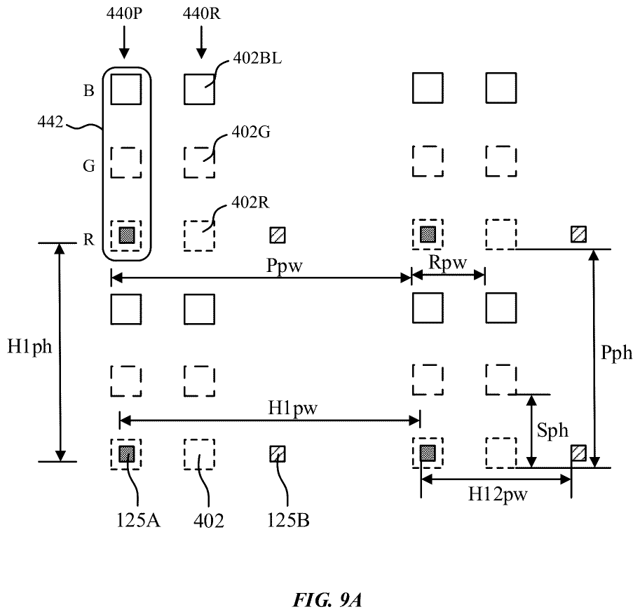

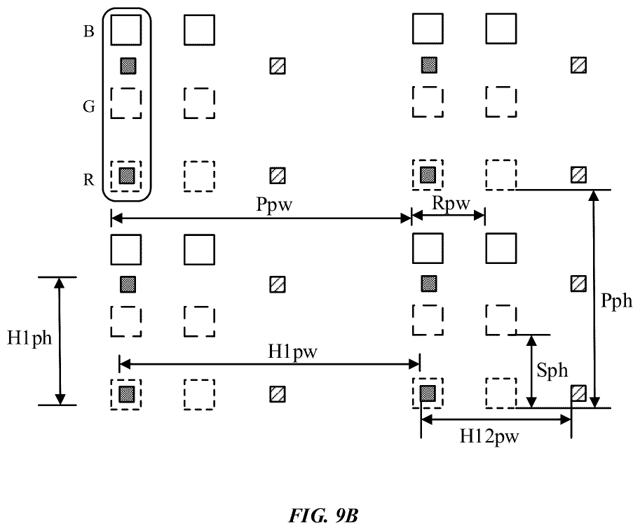

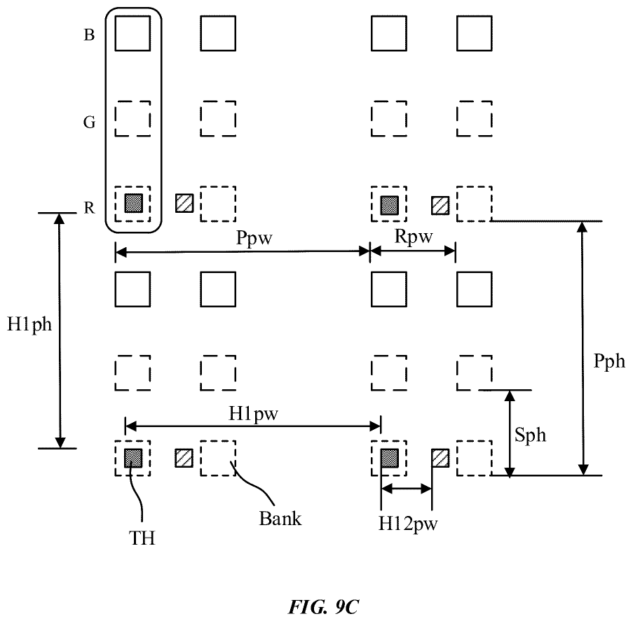

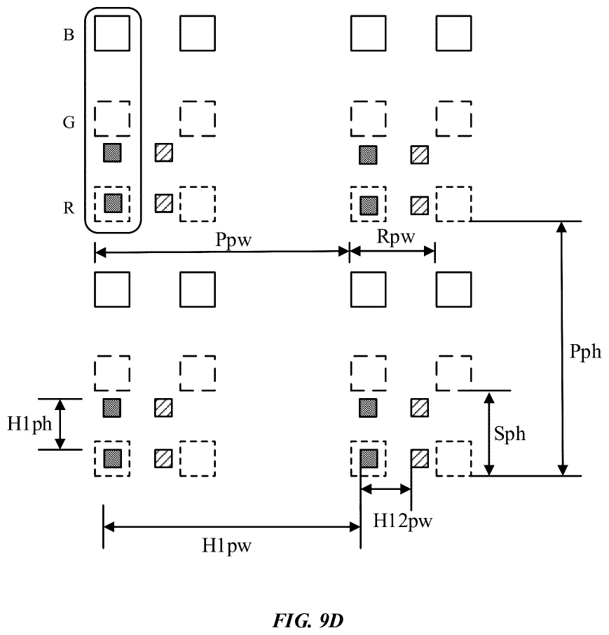

FIGS. 9A-9D are close-up schematic plan view illustrations for arrangements of arrays of transfer heads aligned over arrays of landing pads of display substrates in accordance with embodiments. In the particular embodiments illustrated, arrays of landing pads 402 for a receiving substrate are arranged into primary rows 440P and redundant rows 440R to receive primary and redundant micro devices. Specifically, the micro devices may be micro LEDs populating a display substrate. As shown, the landing pads 402 can be arranged into pixels 442 including landing pads 402BL to receive blue-emitting micro LEDs, landing pads 402G to receive green-emitting LEDs, and landing pads 402R to receive red-emitting LEDs. It is to be appreciated the particular pixel arrangements, and arrangements of different color-emitting micro LEDs is exemplary, and a variety of alternative arrangements are possible.

Referring now to FIG. 9A an array of transfer heads 125 such as that illustrated in FIG. 3A is illustrated arranged over an array of landing pads 402 on a receiving substrate in accordance with an embodiment. As shown, the pixel arrangement can be characterized by a pixel pitch width (Ppw), pixel pitch height (Pph), subpixel pitch height (Sph), and redundancy pitch width (Rpw). The array of transfer heads 125 can be characterized by transfer head pitch width (H1pw) between similarly shaped transfer heads (e.g. the first transfer heads 125A, or the second transfer heads 125B), transfer head pitch height (H1ph) between similarly shaped transfer heads, and a transfer head pitch width (H12pw) between adjacent dissimilarly shaped transfer heads (e.g. between the first transfer heads 125A and the second transfer heads 125B). In the illustrated embodiment, the following conditions H1ph=Pph and (H1pw=Ppw)=2(H12pw) allow for a multiple placement sequence, in which the first transfer heads 125A can place a first array of micro LEDs, followed by placement of a second array of micro LEDs with the second transfer heads 125B.

Referring now to FIG. 9B, a variation of FIG. 9A is illustrated in which additional rows of transfer heads have been inserted. In this case, the additional rows of transfer heads have reduced the distance of H1ph. In the illustrated embodiment, the following conditions H1ph=½(Pph) and (H1pw=Ppw)=2(H12pw) allow for a 4× placement sequence, in which the first transfer heads 125A can sequentially place first and second arrays of micro LEDs, followed by translation and sequential placement of third and fourth array of micro LEDs with the second transfer heads 125B.

Referring now to FIGS. 9C-9D, additional variation are illustrated in which clusters of transfer heads 125 can be arranged with pitches less than redundancy pitch width (Rpw) and/or subpixel pitch height (Sph). Generally, FIGS. 9C-9D illustrate a similar concept as FIGS. 9A-9B, with tighter cluster pitches. In the embodiment illustrated in FIG. 9C, the following conditions H1ph=Pph, H1pw=Ppw, and H12pw<Rpw allow for a multiple placement sequence, in which the first transfer heads 125A can place a first array of micro LEDs, followed by placement of a second array of micro LEDs with the second transfer heads 125B.

In the illustrated embodiment illustrated in FIG. 9D, the following conditions H1ph<Sph and H12pw<Rpw allow for a 4× placement sequence, in which the first transfer heads 125A can sequentially place first and second arrays of micro LEDs, followed by translation and sequential placement of third and fourth array of micro LEDs with the second transfer heads 125B.

In utilizing the various aspects of the embodiments, it would become apparent to one skilled in the art that combinations or variations of the above embodiments are possible for performing single-pick-multiple-print transfer sequences with elastomeric stamps. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A conformable transfer device comprising:
a base substrate; and
a first array of first transfer heads supported by the base substrate, and a second array of second transfer heads supported by the base substrate;
wherein each first transfer head includes a first terminal contact surface extended a first orthogonal distance from the base substrate, and each second transfer head includes a second terminal contact surface extended a second orthogonal distance from the base substrate, wherein the first orthogonal distance is greater than the second orthogonal distance.

2. The conformable transfer device of claim 1, wherein:
each first transfer head includes a first contact mesa, and the first terminal contact surface is on the first contact mesa; and
each second transfer head includes a second contact mesa, and the second terminal contact surface is on the second contact mesa.

3. The conformable transfer device of claim 2, wherein the first contact mesa and the second contact mesa are formed of a same material.

4. The conformable transfer device of claim 3, wherein the same material comprises a polymer.

5. The conformable transfer device of claim 4, wherein the polymer is polydimethylsiloxane (PDMS).

6. The conformable transfer device of claim 2, wherein:
each first transfer head includes a first base mesa, and the first contact mesa extends from a first extension surface of the first base mesa; and
each second transfer head includes a second base mesa, and the second contact mesa extends from a second extension surface of the second base mesa.

7. The conformable transfer device of claim 6, wherein the first base mesa and the second base mesa have a same thickness.

8. The conformable transfer device of claim 6, wherein the first base mesa has a first thickness in an orthogonal direction from the base substrate, and the second base mesa has a second thickness in the orthogonal direction.

9. The conformable transfer device of claim 6, wherein the first base mesa extends directly from the base substrate, and the second base mesa extends directly from the base substrate.

10. The conformable transfer device of claim 6, further comprising a bulk layer on the base substrate, wherein the first base mesa and the second base mesa are integrally formed with the bulk layer and extend from the bulk layer.

11. A micro-transfer printing method comprising:
aligning a conformable transfer device over a donor substrate;
wherein the conformable transfer device includes:
a first array of first transfer heads supported by a base substrate, and a second array of second transfer heads supported by the base substrate;
wherein each first transfer head includes a first terminal contact surface extended a first orthogonal distance from the base substrate, and each second transfer head includes a second terminal contact surface extended a second orthogonal distance from the base substrate, wherein the first orthogonal distance is greater than the second orthogonal distance;
contacting a first array of micro devices on the donor substrate with the first array of first transfer heads while contacting a second array of micro devices on the donor substrate with the second array of second transfer heads; and
picking up both the first array of micro devices from the substrate with the first array of first transfer heads and the second array of micro devices from the base substrate with the second array of second transfer heads.

12. The micro-transfer printing method of claim 11, wherein contacting the first array of micro devices on the donor substrate with the first array of first transfer heads while contacting the second array of micro devices on the donor substrate with the second array of second transfer heads comprises compressing a first height of the first array of first transfer heads more than a second height of the second array of second transfer heads.

13. The micro-transfer printing method of claim 12, further comprising placing the first array of micro devices on a receiving substrate prior to placing the second array of micro devices on the receiving substrate.

14. The micro-transfer printing method of claim 13:
wherein placing the first array of micro devices on the receiving substrate comprises placing the first array of micro devices over a first array of landing pads, and placing the second array of micro devices on the receiving substrate comprises placing the second array of micro devices over a second array of landing pads;
wherein an adhesive film spans over the first array of landing pads and the second array of landing pads; and
wherein the second array of micro devices does not contact the adhesive film while placing the first array of micro devices on the receiving substrate.

15. The micro-transfer printing method of claim 14, wherein placing the first array of micro devices on the receiving substrate comprises punching the first array of micro devices through the adhesive film to contact the first array of landing pads.

16. The micro-transfer printing method of claim 14, wherein placing the first array of micro devices on the receiving substrate comprises placing the first array of micro devices onto the adhesive film spanning over the first array of landing pads.

17. The micro-transfer printing method of claim 16, wherein an array of electrically conductive bonding mesas is embedded within the adhesive film on top of the first array of landing pads.

18. The micro-transfer printing method of claim 14, wherein the first array of landing pads is located on a first array of bank structures, and the second array of landing pads is located on a second array of bank structures.

19. The micro-transfer printing method of claim 18, wherein placing the first array of micro devices on the receiving substrate comprises placing the first array of micro devices over the first array of landing pads while orienting the second array of micro devices laterally adjacent the second array of bank structures.

20. The micro-transfer printing method of claim 19, wherein the adhesive film is a continuous adhesive film spanning over the first array of bank structures, the second array of bank structures, and between the first array of bank structures and the second array of bank structures.

21. The micro-transfer printing method of claim 19:
wherein the adhesive film is a patterned adhesive film spanning over the first array of bank structures and the second array of bank structures; and
wherein the second array of micro devices is not oriented directly over the adhesive film while placing the first array of micro devices on the receiving substrate.
